(19) United States
(12) Patent Application Publication
(10) Pub. No.: US 2002/0079097 A1
(43) Pub. Date: Jun. 27, 2002

(54) Heat sink

(76) Inventors: Seri Lee, Beaverton, OR (US); Lloyd L. Pollard II, Portland, OR (US)

Correspondence Address: SCOTT C. HARRIS, Fish & Richardson P.C., 4350 La Jolla Village Drive, Suite 500, San Diego, CA, 92122, US

(21) Appl. No.: 09/745,562

(22) Filed: Dec. 21, 2000

(51) Int. Cl. F28F 7/00; H05K 7/20

(52) U.S. Cl. 165/185; 165/80.3; 361/704

(57) ABSTRACT

A wire is swaged into a grooved base to provide surface area to a heat sink. The heat sink has a thermally conductive base having a surface with at least one groove formed therein. At least one thermally conductive wire has a first portion secured into the at least one groove and a second portion extending from the surface.

### BACKGROUND

1. Field

The subject matter described herein relates generally to a heat sink for dissipating heat from electronic components.

2. Background

Performance demands on thermal solutions are increasing with increasing microprocessor performance.

Fins may be added to a plate or base to reduce the convective thermal resistance and thereby increase the performance of thermal solutions. The performance of these fins may be related to their total surface area.

Current manufacturing processes for cost-effective, high-aspect-ratio (surface area to volume of material ratio) heat sinks are limited.

Impact extrusion may be relatively expensive for a simple plate and fin arrangement. The base and fins, however, are typically formed of the same material, usually aluminum. This limits the performance due to spreading resistance.

Folded or bonded fins may be epoxied. Epoxy may have a high thermal impedance. The fins can alternatively be brazed to the base, but this may be more expensive.

Plate fins, such as folded fins or extruded fins, may not disrupt the thermal boundary layer, so the convective heat transfer performance of a plate fin may be limited.

High-performance, pin-fin heat sinks may provide omni-directionality to heat sinks. Pin-fin heat sinks may be manufactured using impact extrusion or by cross-cutting extruded plate-fin heat sinks. This may create waste materials.

### DESCRIPTION OF DRAWINGS

FIG. 1 is an isometric view of a heat sink.

FIG. 2 is a diagram of examples of alternative embodiments of the wires.

### DETAILED DESCRIPTION

A heat sink and process of manufacturing is disclosed. Surface area may be cost effectively added by a stitching process that swages a wire into a grooved base. This stitching process may provide high-aspect-ratio fins, high gap aspect ratio (packing density or surface area to volume or material ratio), and low contact resistance between the fins and the base. This fin geometry may inherently disrupt the thermal boundary layer, further reducing the convective resistance from the fins. Additionally, the fins and base may be made of the same material or different materials.

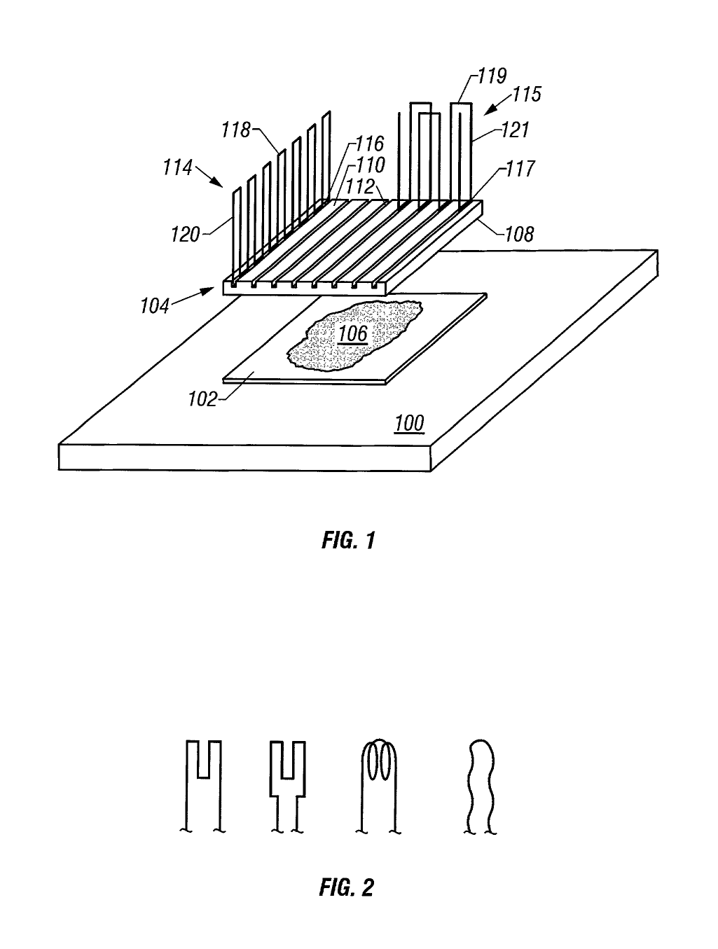

FIG. 1 is an isometric view of a particular heat sink. A printed circuit board or other substrate 100 is typically provided with one or more heat-emitting chips 102 that may be conventionally mounted to the substrate. A heat sink 104 may dissipate heat from the chip. The heat sink may be conventionally mounted on top of the chip, for example, by epoxy 106 or other suitable mounting.

The heat sink 104 may comprise a thermally conductive base 108 having a surface 110 with at least one groove 112 formed therein. At least one thermally conductive wire 114, 115 has first portions 116, 117 secured into the at least one groove and second portions 118, 119 extending from the surface. The first portions may be secured by swaging the first portions into the groove.

The base and wire can be of conventional thermally conductive materials, for example, aluminum or copper. The material should withstand the impact of swaging and maintain good contact between the wire and the groove. The groove and wire may be of different shapes and sizes, for example, rectangular or round. FIG. 2 is a diagram of examples of alternative embodiments of the wires. The wire may be continuous or sectionalized.

The first portions 116, 117 may be compressively held by the at least one groove 112. The second portions 118, 119 may extend from the surface, for example, in an undulating pattern, that is, up and down relative to the surface 110. The second portions may have opposite sides 120, 121 extending perpendicular from the surface. A skilled artisan will recognize that other geometries for the first and second portions are available. For example, the top portions may be arched and the sides may extend at an angle from the surface.

Two or more grooves may be formed in the surface, for example, in straight parallel lines as shown in FIG. 1. Other patterns may be used, for example, curvilinear or crosshatched.

Two or more thermally conductive continuous wires may have their first portions secured into a corresponding one of the grooves, for example, the wire 114 shown in FIG. 1. The thermally conductive continuous wires may also have their first portions swaged into each of the grooves, for example, the wire 115 shown in FIG. 1. A skilled artisan will recognize that other stitching patterns may be employed.

A particular process of forming a heat sink will now be described.

The wire may be formed into two or more first portions and two or more second portions. For example, the wire can be fed off of a spool into a progressive die machine that continuously supplies the wire having the desired shape.

One or more grooves may be formed in the surface of the thermally conductive base. For example, the base can be machined to form the grooves, or the base may be extruded through a die to form the grooves.

The first portions may be compress fitted into the grooves with the second portions of the wire extending from the surface. For example, a bar or swage may be used to force the first portions into the grooves.

This manufacturing process may result in less waste of materials and may eliminate the use of bonding materials.

In conclusion, the heat sink and process of manufacturing disclosed herein provides a cost effective, omni-directional, high-performance wire-fin heat sink.

A number of embodiments of the invention have been described. Nevertheless, it may be understood that various modifications may be made without departing from the spirit and scope of the invention. Accordingly, other embodiments are within the scope of the following claims.

What is claimed is:

1. A heat sink comprising:
a thermally conductive base having a surface with at least one groove formed therein; and
at least one thermally conductive wire having at least one first portion secured into the at least one groove and at least one second portion extending from the surface.

2. The heat sink of claim 1 wherein the at least one second portion comprises two or more second portions extending from the surface in an undulating pattern.

3. The heat sink of claim 1 wherein the at least one first portion is compressively held by the at least one groove.

4. The heat sink of claim 1 wherein the at least one second portion has opposite sides extending perpendicular from the surface.

5. The heat sink of claim 1 wherein the at least one groove comprises two or more grooves formed in the surface, and the at least one thermally conductive wire comprises two or more thermally conductive wires each having their first portions secured into a corresponding one of the grooves.

6. The heat sink of claim 1 wherein the at least one groove comprises two or more grooves formed in the surface, and the at least one thermally conductive wire comprises two or more thermally conductive wires each having their first portions secured into each of the grooves.

7. The heat sink of claim 6 wherein the two or more grooves are parallel.

8. The heat sink of claim 1 wherein the at least one thermally conductive wire is continuous.

9. The heat sink of claim 1 wherein the at least one thermally conductive wire comprises a first material and the thermally conductive base comprises a second material, wherein the first material is dissimilar to the second material.

10. A heat sink comprising:
a thermally conductive base having a surface with two or more parallel grooves formed therein; and
two or more thermally conductive continuous wires each having first portions and second portions, the first portions of each wire being swaged into a corresponding one of the grooves and the second portions of each wire extending perpendicular from the surface.

11. The heat sink of claim 10 wherein the two or more thermally conductive continuous wires comprise a first material and the thermally conductive base comprises a second material, wherein the first material is dissimilar to the second material.

12. A heat sink comprising:
a thermally conductive base having a surface with two or more parallel grooves formed therein; and
two or more thermally conductive continuous wires each having first portions and second portions, the first portions of each wire being swaged into each of the grooves and the second portions of each wire extending perpendicular from the surface.

13. The heat sink of claim 12 wherein the two or more thermally conductive continuous wires comprise a first material and the thermally conductive base comprises a second material, wherein the first material is dissimilar to the second material.

14. A process of forming a heat sink comprising:
forming at least one thermally conductive wire into two or more first portions and two or more second portions;
forming at least one groove in a surface of a thermally conductive base; and
compress fitting the two or more first portions into the at least one groove with the two or more second portions extending from the surface.

15. The process of claim 14 further comprising feeding the thermally conductive continuous wire into a progressive die machine.
